(19) United States
(12) Patent Application Publication
(10) Pub. No.: US 2025/0279622 A1
(43) Pub. Date: Sep. 4, 2025

(54) LASER CHAMBER, GAS LASER DEVICE, AND ELECTRONIC DEVICE MANUFACTURING METHOD

(71) Applicant: Gigaphoton Inc., Tochigi (JP)

(72) Inventor: Hitoshi OHGA, Oyama-shi (JP)

(73) Assignee: Gigaphoton Inc., Tochigi (JP)

(21) Appl. No.: 19/046,184

(22) Filed: Feb. 5, 2025

(30) Foreign Application Priority Data
Mar. 4, 2024 (JP) 2024-032140

(51) Int. Cl. H01S 3/036; G03F 7/20; H01S 3/038

(52) U.S. Cl. CPC H01S 3/036; G03F 7/2006; H01S 3/0381; H01S 3/0382

(57) ABSTRACT

A laser chamber of a gas laser device outputting laser light including a container filled with a laser gas; a first electrode extending in a first direction and arranged in the container; a second electrode arranged at a position closer to an inner wall of the container than the first electrode while extending in the first direction and facing the first electrode in a second direction orthogonal to the first direction; a fan causing the laser gas to flow through a discharge space between the first and second electrodes; an insulating guide arranged on a downstream side of the second electrode; and a vortex dividing member including structures extending in the first direction and arranged discretely along a direction in which the laser gas flows on a downstream side of the insulating guide, and dividing a vortex generated by a part of a flow of the laser gas.

### CROSS-REFERENCE TO RELATED APPLICATIONS

The present application claims the benefit of Japanese Patent Application No. 2024-032140, filed on Mar. 4, 2024, the entire contents of which are hereby incorporated by reference.

### BACKGROUND

### 1. Technical Field

The present disclosure relates to a laser chamber, a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: U.S. Pat. No. 6,442,181

### SUMMARY

A laser chamber, according to an aspect of the present disclosure, of a gas laser device configured to output laser light, includes a container filled with a laser gas; a first electrode extending in a first direction and arranged in the container; a second electrode arranged at a position closer to an inner wall of the container than the first electrode while extending in the first direction and facing the first electrode in a second direction orthogonal to the first direction; a fan configured to cause the laser gas to flow through a discharge space between the first electrode and the second electrode; an insulating guide arranged on a downstream side of the second electrode; and a vortex dividing member including a plurality of structures extending in the first direction and arranged discretely along a direction in which the laser gas flows on a downstream side of the insulating guide, and configured to divide a vortex generated by a part of a flow of the laser gas.

A gas laser device, according to an aspect of the present disclosure, is configured to output laser light and includes an optical resonator and a laser chamber arranged to cause an optical path of the optical resonator to pass therethrough. Here, the laser chamber includes a container filled with a laser gas; a first electrode extending in a first direction and arranged in the container; a second electrode arranged at a position closer to an inner wall of the container than the first electrode while extending in the first direction and facing the first electrode in a second direction orthogonal to the first direction; a fan configured to cause the laser gas to flow through a discharge space between the first electrode and the second electrode; an insulating guide arranged on a downstream side of the second electrode; and a vortex dividing member including a plurality of structures extending in the first direction and arranged discretely along a direction in which the laser gas flows on a downstream side of the insulating guide, and configured to divide a vortex generated by a part of a flow of the laser gas.

An electronic device manufacturing method, according to an aspect of the present disclosure includes generating laser light using a gas laser device, outputting the laser light to an exposure apparatus, and exposing a photosensitive substrate to the laser light in the exposure apparatus to manufacture an electronic device. Here, the gas laser device is configured to output the laser light and includes an optical resonator and a laser chamber arranged to cause an optical path of the optical resonator to pass therethrough. The laser chamber includes a container filled with a laser gas; a first electrode extending in a first direction and arranged in the container; a second electrode arranged at a position closer to an inner wall of the container than the first electrode while extending in the first direction and facing the first electrode in a second direction orthogonal to the first direction; a fan configured to cause the laser gas to flow through a discharge space between the first electrode and the second electrode; an insulating guide arranged on a downstream side of the second electrode; and a vortex dividing member including a plurality of structures extending in the first direction and arranged discretely along a direction in which the laser gas flows on a downstream side of the insulating guide, and configured to divide a vortex generated by a part of a flow of the laser gas.

### BRIEF DESCRIPTION OF THE DRAWINGS

Embodiments of the present disclosure will be described below merely as examples with reference to the accompanying drawings.

FIG. 1 is a side view schematically showing the configuration of a gas laser device according to a comparative example.

FIG. 2 is a sectional view schematically showing the configuration of the gas laser device according to the comparative example.

FIG. 3 is a sectional view showing in detail the configuration of the vicinity of a main electrode of a laser chamber.

FIG. 4 is a sectional view showing in detail the configuration of the vicinity of the main electrode of the laser chamber according to a first embodiment.

FIG. 5 is a view showing an example of a flow of a laser gas in the first embodiment.

FIG. 6 is a sectional view showing in detail the configuration of the vicinity of the main electrode of the laser chamber according to a second embodiment.

FIG. 7 is a view showing an example of the flow of the laser gas in the second embodiment.

FIG. 8 is a sectional view showing in detail the configuration of the vicinity of the main electrode of the laser chamber according to a third embodiment.

FIG. 9 is a view showing an example of the flow of the laser gas in the third embodiment.

FIG. 10 is a sectional view showing in detail the configuration of the vicinity of the main electrode of the laser chamber according to a fourth embodiment.

FIG. 11 is a diagram schematically showing a configuration example of an exposure apparatus.

### DESCRIPTION OF EMBODIMENTS

### <Contents>

### 1. Comparative Example

### 1.1 Configuration

### 1.2 Operation

### 1.3 Problem

### 2. First Embodiment

### 2.1 Configuration

### 2.2 Operation

### 2.3 Effect

### 3. Second Embodiment

### 3.1 Configuration

### 3.2 Operation

### 3.3 Effect

### 4. Third Embodiment

### 4.1 Configuration

### 4.2 Operation

### 4.3 Effect

### 5. Fourth Embodiment

### 5.1 Configuration

### 5.2 Operation

### 5.3 Effect

### 6. Electronic Device Manufacturing Method

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

First, a comparative example of the present disclosure will be described. The comparative example of the present disclosure is an example recognized by the applicant as known only by the applicant, and is not a publicly known example admitted by the applicant.

### 1.1 Configuration

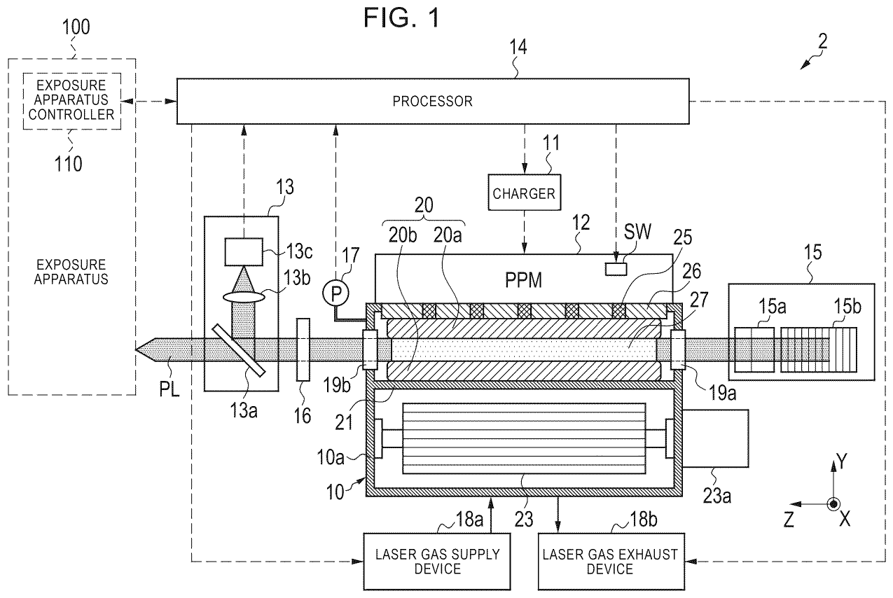

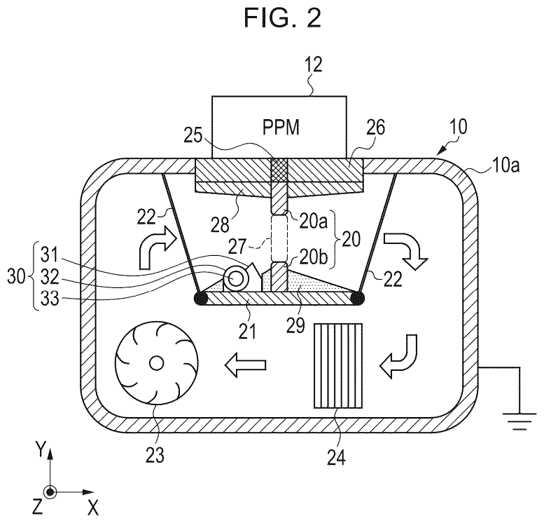

The configuration of a gas laser device 2 according to the comparative example will be described using FIGS. 1 and 2. FIG. 1 schematically shows the configuration of the gas laser device 2. FIG. 2 is a sectional view of the gas laser device 2 shown in FIG. 1 viewed from a Z direction. The gas laser device 2 is a discharge-excitation-type gas laser device that discharges and excites a laser gas, and is, for example, an excimer laser device.

In FIG. 1, the travel direction of pulse laser light PL output from the gas laser device 2 is defined as the Z direction. A discharge direction to be described later is defined as a Y direction. A direction orthogonal to the Z direction and the Y direction is defined as an X direction. Here, the pulse laser light PL is an example of the “laser light” according to the technology of the present disclosure. The Z direction is an example of the “first direction” according to the technology of the present disclosure. The Y direction is an example of the “second direction” according to the technology of the present disclosure. The X direction is an example of the “third direction” according to the technology of the present disclosure.

In FIG. 1, the gas laser device 2 includes a laser chamber 10, a charger 11, a pulse power module (PPM) 12, a pulse energy measurement unit 13, a processor 14, a pressure sensor 17, and a laser resonator. The laser resonator is configured of a line narrowing module 15 and an output coupling mirror 16.

The laser chamber 10 includes, for example, a container 10a made of aluminum metal plated with nickel on the surface thereof. As shown in FIGS. 1 and 2, a main electrode 20, a ground plate 21, wirings 22, a fan 23, a heat exchanger 24, an insulating guide 28, a conductive guide 29, and a preionization electrode 30 are provided in the container 10a. The preionization electrode 30 includes a preionization outer electrode 31, a dielectric pipe 32, and a preionization inner electrode 33.

A laser gas containing fluorine as a laser medium is enclosed in the container 10a. The laser gas includes, for example, argon, krypton, xenon, or the like as a rare gas, neon, helium, or the like as a buffer gas, and fluorine, chlorine, or the like as a halogen gas. Further, an opening is formed in the container 10a. An electrically insulating plate 26 in which a feedthrough 25 is embedded is attached to the container 10a via an O-ring (not shown) so as to close the opening. The PPM 12 is arranged on the electrically insulating plate 26. The container 10a is grounded.

The PPM 12 includes a charging capacitor (not shown) and is connected to the main electrode 20 via the feedthrough 25. The PPM 12 includes a switch SW for causing discharge to occur at the main electrode 20. The charger 11 is connected to the charging capacitor of the PPM 12. Hereinafter, discharge occurring at the main electrode 20 is referred to as main discharge.

The main electrode 20 includes a cathode electrode 20a and an anode electrode 20b. The cathode electrode 20a and the anode electrode 20b are arranged in the container 10a so that discharge surfaces of the both face each other. The space between the discharge surface of the cathode electrode 20a and the discharge surface of the anode electrode 20b is referred to as a discharge space 27. Each of the cathode electrode 20a and the anode electrode 20b extends in the Z direction.

The cathode electrode 20a is supported by the electrically insulating plate 26 on a surface opposite to the discharge surface thereof, and is connected to the feedthrough 25. That is, the cathode electrode 20a is arranged closer to the inner wall 10b of the container 10a than the anode electrode 20b while facing the anode electrode 20b. The anode electrode 20b is supported by the ground plate 21 on a surface opposite to the discharge surface thereof. The anode electrode 20b is an example of the “first electrode” according to the technology of the present disclosure. The cathode electrode 20a is an example of the “second electrode” according to the technology of the present disclosure.

The ground plate 21 is connected to the container 10a via the wirings 22. The container 10a is grounded. Therefore, the ground plate 21 is grounded via the wirings 22. An end part of the ground plate 21 in the Z direction is fixed to the container 10a.

The fan 23 is a cross flow fan for circulating the laser gas in the container 10a, and is arranged on the opposite side of the discharge space 27 with respect to the ground plate 21. A motor 23a for rotationally driving the fan 23 is connected to the container 10a.

The laser gas blown out from the fan 23 flows into the discharge space 27. The flow direction of the laser gas flowing into the discharge space 27 is substantially parallel to the X direction. The laser gas flowing out from the discharge space 27 is sucked into the fan 23 via the heat exchanger 24. The heat exchanger 24 changes the temperature of the laser gas by performing heat exchange between a refrigerant supplied to the inside of the heat exchanger 24 and the laser gas.

The insulating guide 28 is arranged on a surface of the electrically insulating plate 26 facing the discharge space 27 so as to sandwich the cathode electrode 20a. The insulating guide 28 is formed in a shape to guide the flow of the laser gas so that the laser gas from the fan 23 efficiently flows between the cathode electrode 20a and the anode electrode 20b. The insulating guide 28 and the electrically insulating plate 26 are made of, for example, ceramics such as alumina (Al₂O₃) having low reactivity with the fluorine gas.

The conductive guide 29 is arranged on a surface of the ground plate 21 facing the discharge space 27 so as to sandwich the anode electrode 20b. Similarly to the insulating guide 28, the conductive guide 29 is formed in a shape to guide the flow of the laser gas so that the laser gas from the fan 23 efficiently flows between the cathode electrode 20a and the anode electrode 20b. The conductive guide 29 is made of, for example, a porous nickel metal having low reactivity with the fluorine gas.

A laser gas supply device 18a and a laser gas exhaust device 18b are connected to the laser chamber 10. The laser gas supply device 18a includes a valve and a flow rate control valve, and is connected to a gas cylinder accommodating the laser gas. The laser gas exhaust device 18b includes a valve and an exhaust pump.

At end parts of the container 10a, windows 19a, 19b for outputting light generated in the container 10a to the outside are provided, respectively. The laser chamber 10 is arranged such that the optical path of the optical resonator passes through the discharge space 27 and the windows 19a, 19b.

The line narrowing module 15 includes a prism 15a and a grating 15b. The prism 15a transmits the light output from the laser chamber 10 through the window 19a toward the grating 15b while expanding the beam width of the light.

The grating 15b is arranged in the Littrow arrangement in which the incident angle and the diffraction angle are the same. The grating 15b is a wavelength selection element that selectively extracts light having a wavelength near a particular wavelength in accordance with the diffraction angle. The spectral width of the light returning from the grating 15b to the laser chamber 10 via the prism 15a is line-narrowed.

The output coupling mirror 16 transmits a part of the light output from the laser chamber 10 through the window 19b, and reflects the other part back into the laser chamber 10. The surface of the output coupling mirror 16 is coated with a partial reflection film.

Light output from the laser chamber 10 reciprocates between the line narrowing module 15 and the output coupling mirror 16, and is amplified each time the light passes through the discharge space 27. A part of the amplified light is output as the pulse laser light PL via the output coupling mirror 16. The wavelength of the pulse laser light PL is in an ultraviolet range of 150 nm to 380 nm, and is, for example, an oscillation wavelength of an excimer laser device.

The pulse energy measurement unit 13 is arranged on the optical path of the pulse laser light PL output via the output coupling mirror 16. The pulse energy measurement unit 13 includes a beam splitter 13a, a light concentrating optical system 13b, and an optical sensor 13c.

The beam splitter 13a transmits the pulse laser light PL with a high transmittance and reflects a part of the pulse laser light PL toward the light concentrating optical system 13b. The light concentrating optical system 13b concentrates the light reflected by the beam splitter 13a on a light receiving surface of the optical sensor 13c. The optical sensor 13c measures the pulse energy of the light concentrated on the light receiving surface, and outputs the measurement value to the processor 14.

The pressure sensor 17 detects the gas pressure in the container 10a, and outputs the detection value to the processor 14. The processor 14 determines the gas pressure of the laser gas in the container 10a based on the detection value of the gas pressure and the charge voltage of the charger 11.

The charger 11 is a high voltage power source that supplies the charge voltage to the charging capacitor included in the PPM 12. The switch SW of the PPM 12 is controlled by the processor 14. When the switch SW is turned ON from OFF, the PPM 12 generates a high voltage pulse from the electric energy held in the charging capacitor and applies the high voltage pulse to the main electrode 20.

The processor 14 is a processing device that transmits and receives various signals to and from an exposure apparatus controller 110 provided in an exposure apparatus 100. For example, the exposure apparatus controller 110 transmits, to the processor 14, a target pulse energy of the pulse laser light PL to be output to the exposure apparatus 100, an oscillation trigger signal, and the like.

The processor 14 generally controls operation of each component of the gas laser device 2 based on various signals transmitted from the exposure apparatus controller 110, the measurement value of the pulse energy, the detection value of the gas pressure, and the like.

The processor 14 functions as a controller of the gas laser device 2. For example, the processor 14 is a processing device including a storage device in which a control program is stored and a central processing unit (CPU) that executes the control program. The processor 14 is specifically configured or programmed to perform various processes included in the present disclosure. The storage device is a non-transitory computer-readable storage medium, and includes, for example, a memory that is a main storage device and a storage that is an auxiliary storage device. Here, the storage device may be a semiconductor memory, a hard disk drive (HDD) device, a solid state drive (SSD) device, or a combination thereof.

Here, the gas laser device 2 is not necessarily limited to a line narrowing laser device, and may be a laser device that outputs natural oscillation light. For example, a high reflection mirror may be arranged in place of the line narrowing module 15.

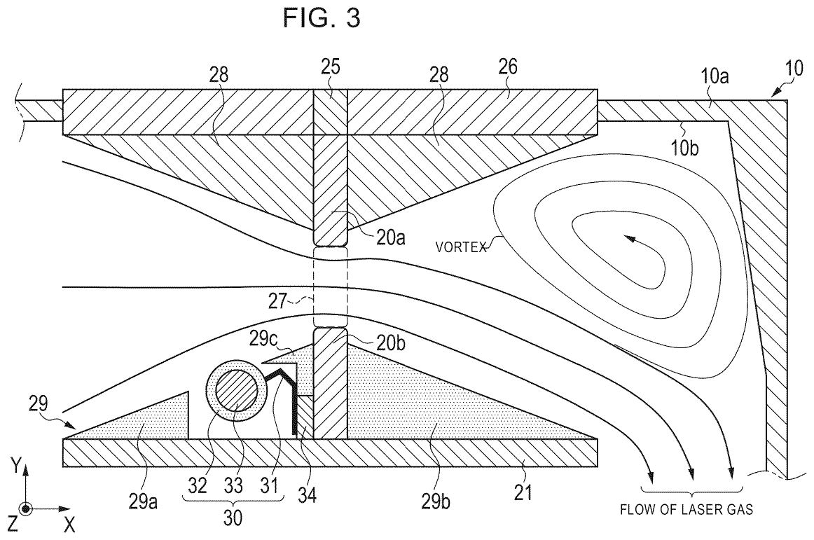

FIG. 3 shows in detail the configuration of the vicinity of the main electrode 20 of the laser chamber 10. In the following description, the upstream side refers to a side, with respect to the discharge space 27, from which the laser gas flows into the discharge space 27. The downstream side refers to a side, with respect to the discharge space 27, to which the laser gas flows out from the discharge space 27.

The preionization outer electrode 31 is arranged between the anode electrode 20b and the dielectric pipe 32, and is held in contact with a side surface of a holding member 34 made of metal. The holding member 34 is fixed to an upstream side surface of the anode electrode 20b. The preionization inner electrode 33 is arranged in the dielectric pipe 32, and the preionization outer electrode 31 is in contact with the outside of the dielectric pipe 32.

The insulating guide 28 is arranged so as to cover the upstream and downstream side surfaces of the cathode electrode 20a. The surface of the insulating guide 28 is inclined so as to be closer to the electrically insulating plate 26 as the distance from the cathode electrode 20a increases.

The conductive guide 29 includes a first guide member 29a, a second guide member 29b, and a third guide member 29c. The first guide member 29a and the third guide member 29c are arranged upstream of the anode electrode 20b. The second guide member 29b is arranged downstream of the anode electrode 20b.

The first guide member 29a is arranged on the ground plate 21 so as to guide the laser gas to the discharge space 27. The dielectric pipe 32 is arranged between the first guide member 29a and the anode electrode 20b so as to be spaced apart from each of the ground plate 21 and the anode electrode 20b. The second guide member 29b is arranged on the ground plate 21 downstream of the anode electrode 20b so as to cover the downstream side surface of the anode electrode 20b.

The third guide member 29c is arranged between the dielectric pipe 32 and the anode electrode 20b so as to cover the upstream side surface of the anode electrode 20b and to guide the laser gas to the discharge space 27. The third guide member 29c is close to the dielectric pipe 32.

The surface of the conductive guide 29 is inclined as a whole so as to be closer to the ground plate 21 as the distance from the anode electrode 20b increases.

As described above, the insulating guide 28 and the conductive guide 29 form a flow path of the laser gas. To maximize the flow rate of the laser gas flowing through the discharge space 27 and to suppress acoustic waves generated by main discharge from being reflected and returning to the discharge space 27, the flow path width in the Y direction is set to be wider as the distance from the discharge space 27 increases. Further, to suppress the acoustic waves generated by main discharge from being reflected by the inner wall 10b in the container 10a and returning to the discharge space 27, a part of the inner wall 10b facing the discharge space 27 in the X direction is inclined with respect to the Y direction which is the discharge direction. Here, the acoustic waves are compressional waves of the laser gas.

Each of the upstream and downstream side surfaces of the cathode electrode 20a in the vicinity of the discharge surface thereof are not covered with the insulating guide 28, and the cathode electrode 20a protrudes from the surface of the insulating guide 28 toward the anode electrode 20b. Thus, the discharge surface of the cathode electrode 20a is spaced apart from the surface of the insulating guide 28.

Each of the upstream and downstream side surfaces of the anode electrode 20b in the vicinity of the discharge surface thereof are not covered with the conductive guide 29, and the anode electrode 20b protrudes from the surface of the conductive guide 29 toward the cathode electrode 20a. Thus, the discharge surface of the anode electrode 20b is spaced apart from the surface of the conductive guide 29.

### 1.2 Operation

Next, operation of the gas laser device 2 according to the comparative example will be described. First, the processor 14 controls the laser gas supply device 18a to supply the laser gas into the container 10a of the laser chamber 10, and drives the motor 23a to rotate the fan 23. As a result, as indicated by arrows in FIG. 2, the laser gas filled in the container 10a circulates.

The processor 14 receives the target pulse energy and the oscillation trigger signal transmitted from the exposure apparatus controller 110. Here, the oscillation trigger signal is a signal for instructing the gas laser device 2 to output one pulse of the pulse laser light PL. The processor 14 sets the charge voltage corresponding to the target pulse energy in the charger 11. The processor 14 operates the switch SW of the PPM 12 in synchronization with the oscillation trigger signal.

When the switch SW of the PPM 12 is turned ON from OFF, a voltage is applied to each between the preionization inner electrode 33 and the preionization outer electrode 31 of the preionization electrode 30 and between the cathode electrode 20a and the anode electrode 20b. As a result, corona discharge occurs at the preionization electrode 30, and ultraviolet (UV) light is generated. When the laser gas in the discharge space 27 is irradiated with the UV light, the laser gas is preionized.

Thereafter, when the voltage between the cathode electrode 20a and the anode electrode 20b reaches a breakdown voltage, main discharge occurs in the discharge space 27. When the discharge direction of main discharge is defined as a direction in which electrons flow, the discharge direction is the direction from the cathode electrode 20a toward the anode electrode 20b. When main discharge occurs, the laser gas in the discharge space 27 is excited to emit light.

The light emitted from the laser gas is reflected by the line narrowing module 15 and the output coupling mirror 16 and reciprocates in the laser resonator, thereby performing laser oscillation. The light line-narrowed by the line narrowing module 15 is output from the output coupling mirror 16 as the pulse laser light PL.

A part of the pulse laser light PL output from the output coupling mirror 16 enters the pulse energy measurement unit 13. The pulse energy measurement unit 13 measures the pulse energy of the entering pulse laser light PL, and outputs the measurement value to the processor 14.

The processor 14 calculates a difference ΔE between the measurement value of the pulse energy and the target pulse energy. The processor 14 performs feedback control on the charge voltage based on the difference ΔE so that the measurement value of the pulse energy becomes the target pulse energy.

When the charge voltage is higher than a maximum value of an allowable range, the processor 14 controls the laser gas supply device 18a to supply the laser gas into the container 10a until a predetermined pressure is reached. Further, when the charge voltage is lower than a minimum value of the allowable range, the processor 14 controls the laser gas exhaust device 18b to exhaust the laser gas from the container 10a until a predetermined pressure is reached.

The pulse laser light transmitted through the pulse energy measurement unit 13 enters the exposure apparatus 100.

### 1.3 Problem

FIG. 3 shows a flow of the laser gas circulating through the container 10a. The laser gas having passed through the discharge space 27 from the upstream side changes the travel direction at the space on the downstream side, and then flows toward the heat exchanger 24. At the space on the downstream side, there is a region in which stagnation occurs. In this region, a vortex is generated by a part of the flow of the laser gas. The vortex compresses the flow path of the laser gas and serves as a resistance source for the flow of the laser gas. As a result, the flow rate of the laser gas flowing through the discharge space 27 decreases, discharge products generated by main discharge remain in the discharge space 27, and the main discharge becomes unstable, so that the energy stability of the pulse laser light PL deteriorates.

Accordingly, an object of the present disclosure is to provide a laser chamber, a gas laser device, and an electronic device manufacturing method that can improve the flow rate of the laser gas flowing through the discharge space 27.

### 2. First Embodiment

### 2.1 Configuration

The gas laser device 2 according to a first embodiment of the present disclosure has a configuration similar to that of the gas laser device 2 according to the comparative example except that the configuration of the laser chamber 10 is different.

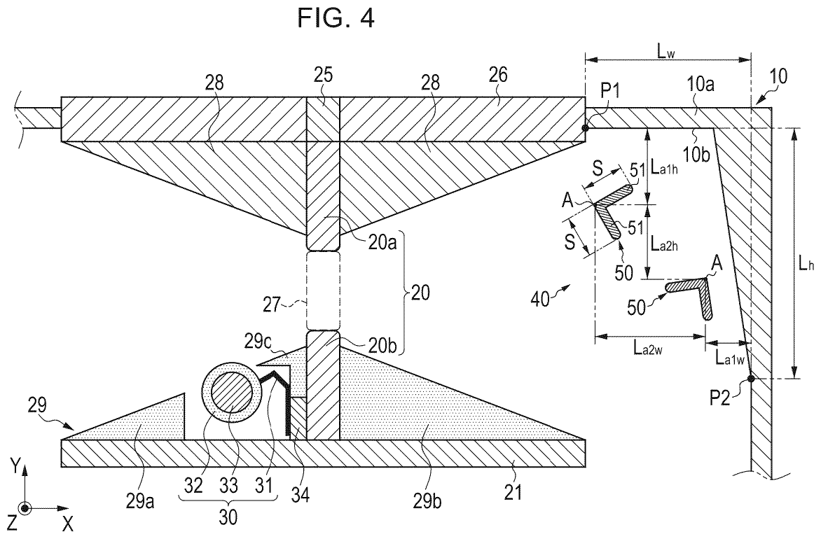

FIG. 4 shows in detail the configuration of the vicinity of the main electrode 20 of the laser chamber 10 according to the first embodiment. In the present embodiment, a vortex dividing member 40 for dividing the vortex described above is provided in the container 10a. In the present embodiment, the vortex dividing member 40 is configured of a plurality of structures 50 discretely arranged along the flow of the laser gas on the downstream side with respect to the insulating guide 28 arranged on the downstream side of the cathode electrode 20a. The plurality of structures 50 are arranged with a gap therebetween. FIG. 4 shows a case in which the vortex dividing member 40 includes two structures 50.

The structure 50 has an L-shaped cross section in an XY plane perpendicular to the Z direction. The structure 50 is a so-called bracket. The structure 50 extends in the Z direction while maintaining the same cross-sectional shape, and both end portions in the Z direction are fixed to the inner wall 10b of the container 10a. In addition to having the both end portions thereof fixed to the inner wall 10b, the structure 50 may be supported by a support column (not shown) connected to the inner wall 10b.

The structure 50 is preferably formed of, for example, aluminum on which nickel electroless plating is performed, alumina ceramic, nickel, or the like.

The structure 50 has two straight portions 51 perpendicular to each other in the XY plane. The two straight portions 51 have the same length and are connected to each other at the end portions thereof. The structure 50 is arranged such that each of the two straight portions 51 is inclined with respect to the Y direction, which is the discharge direction, to suppress reflected acoustic waves from returning to the discharge space 27.

The size and arrangement of the plurality of structures 50 are preferably determined such that the following conditions are satisfied in order to divide the vortex and suppress acoustic waves from returning to the discharge space 27.

First, in the XY plane, a point at which the inner wall 10b is in contact with the insulating guide 28 on the downstream side of the cathode electrode 20a is defined as a first point P1, and a point at which the inner wall 10b becomes parallel to the discharge direction is defined as a second point P2. In the present disclosure, “being in contact” is not limited to “being contacted”, but includes “being close.” In FIG. 4, the first point P1 is the point at which the inner wall 10b is connected to the electrically insulating plate 26 in the XY plane. The second point P2 is an end portion of an inclined surface of the inner wall 10b that is inclined with respect to the discharge direction. Further, a distance between the first point P1 and the second point P2 in the Y direction is defined as a first distance Lₕ, and a distance between the first point P1 and the second point P2 in the X direction is defined as a second distance L_{w}.

When the number of structures 50 included in the vortex dividing member 40 is N and the length of each of the two straight portions 51 is S, it is preferable that the following Expressions (1) and (2) are satisfied.

S≤Lₕ/(2N) (1)

S≤L_{w}/(2N) (2)

A point at which the two straight portions 51 are connected to each other is defined as an apex A of the structure 50. When the distance in the Y direction between the apex A of the structure 50 closest to the first point P1 among the plurality of structures 50 and the inner wall 10b is defined as Lₐ₁ₕ, the following Expression (3) is preferably satisfied.

0<Lₐ₁ₕ≤Lₕ/(2N) (3)

Further, when the distance in the X direction between the apex A of the structure 50 closest to the second point P2 among the plurality of structures 50 and the inner wall 10b is defined as L_{a1w}, the following Expression (4) is preferably satisfied.

0<L_{a1w}≤L_{w}/(2N) (4)

Here, the above Expressions (3) and (4) include a range in which the orientation of the structure 50 in the XY plane is limited in order to avoid contacting with the inner wall 10b.

When the distance in the Y direction between the apexes A of two adjacent structures 50 is defined as Lₐ₂ₕ, the following Expression (5) is preferably satisfied.

Lₐ₂ₕ≤(Lₕ-S/2-Lₐ₁ₕ)/(N−1) (5)

Further, when the distance in the X direction between the apexes A of two adjacent structures 50 is defined as L_{a2w}, the following Expression (6) is preferably satisfied.

L_{a2w}≤(L_{w}-S/2-L_{a1w})/(N−1) (6)

Here, two adjacent structures 50 refer to a combination of one structure 50 and another structure 50 having an apex A closest to the apex A of the one structure 50.

### 2.2 Operation

Operation of the gas laser device 2 according to the present embodiment is similar to that of the comparative example except that the effect caused by provision of the vortex dividing member 40 in the container 10a is different.

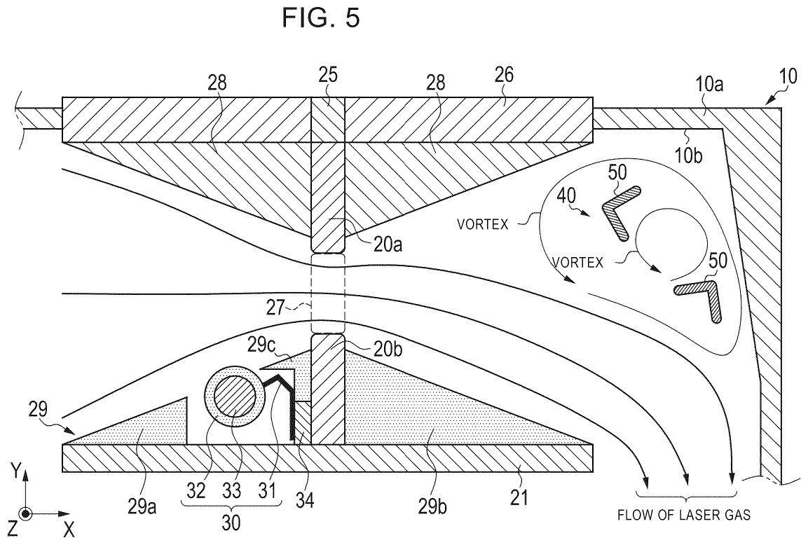

FIG. 5 shows an example of the flow of the laser gas in the first embodiment. As shown in FIG. 5, in the present embodiment, as in the comparative example, stagnation occurs in a space on the downstream side with respect to the discharge space 27, and a vortex is generated in a region at which the stagnation is occurring, but the vortex is divided into a plurality of small vortices by the vortex dividing member 40.

### 2.3 Effect

In the present embodiment, since the vortex is divided into a plurality of small vortices by the vortex dividing member 40, a flow path resistance of the laser gas due to the vortex is reduced. As a result, the flow rate of the laser gas flowing through the discharge space 27 is increased and discharge products remaining in the discharge space 27 are reduced, so that the stability of main discharge is improved and the energy stability of the pulse laser light PL is improved. The applicant of the present invention performed a simulation using “SOLIDWORKS 2019 Flow Simulation” which is a thermal fluid analysis software of Solidworks Corporation, and confirmed that, in the present embodiment, the flow rate was improved by 2% as compared with the comparative example.

Further, the vortex dividing member 40 is configured by the plurality of structures 50 arranged discretely along the flow of the laser gas, and since the area thereof for reflecting acoustic waves is small, it is possible to suppress acoustic waves from being reflected by the vortex dividing member 40 and returning to the discharge space 27. Further, since the two straight portions 51 are arranged to be inclined with respect to the Y direction, which is the discharge direction, acoustic waves can be further suppressed from returning to the discharge space 27. By suppressing acoustic waves from returning to the discharge space 27 as described above, the energy stability of the pulse laser light PL is further improved.

### 3. Second Embodiment

### 3.1 Configuration

The gas laser device 2 according to a second embodiment of the present disclosure has a configuration similar to that of the gas laser device 2 according to the first embodiment except that the configuration of the laser chamber 10 is different.

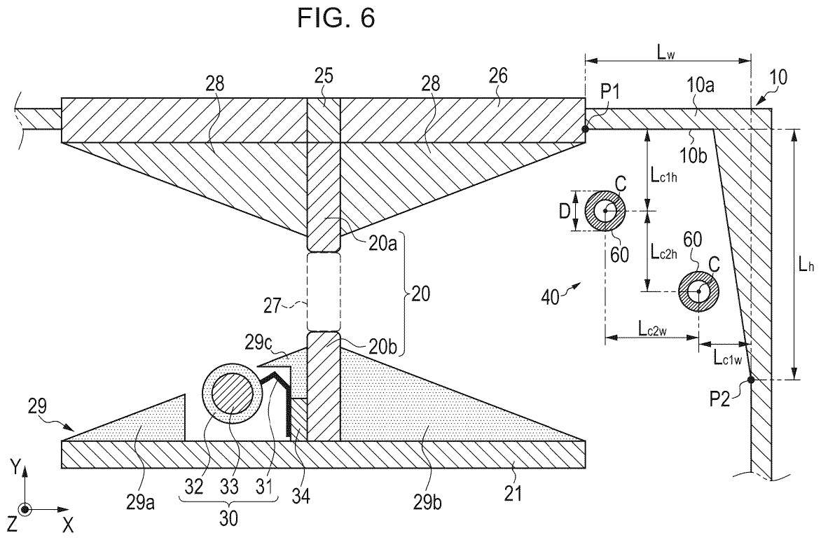

FIG. 6 shows in detail the configuration of the vicinity of the main electrode 20 of the laser chamber 10 according to the second embodiment. In the present embodiment, similarly to the first embodiment, the vortex dividing member 40 for dividing the vortex described above is provided in the container 10a. In the present embodiment, the vortex dividing member 40 is configured of a plurality of structures 60 discretely arranged along the flow of the laser gas on the downstream side with respect to the insulating guide 28 arranged on the downstream side of the cathode electrode 20a. FIG. 6 shows a case in which the vortex dividing member 40 includes two structures 60.

The structure 60 has the same configuration as the structure 50 of the first embodiment except that the cross-sectional shape thereof is different. The structure 60 has a circular outer shape in a cross section in the XY plane perpendicular to the Z direction. The structure 60 is a so-called cylindrical bar. In the present embodiment, the structure 60 is a hollow cylinder having a circular hollow portion. Here, the structure 60 may be a solid cylinder not having a hollow portion.

The structure 60 extends in the Z direction while maintaining the same cross-sectional shape, and both end portions in the Z direction are fixed to the inner wall 10b of the container 10a. In addition to having the both end portions thereof fixed to the inner wall 10b, the structure 60 may be supported by a support column (not shown) connected to the inner wall 10b.

The structure 60 is preferably formed of, for example, aluminum on which nickel electroless plating is performed, alumina ceramic, nickel, or the like.

The size and arrangement of the plurality of structures 60 are preferably determined such that the following conditions are satisfied in order to divide the vortex and suppress acoustic waves from returning to the discharge space 27. Here, definitions of the first point P1, the second point P2, the first distance Lₕ, and the second distance L_{w} are similar to those in the first embodiment.

When the number of structures 60 included in the vortex dividing member 40 is N and an outer diameter of the structure 60 is D, the following Expressions (7) and (8) are preferably satisfied.

D≤Lₕ/(2N) (7)

D≤L_{w}/(2N) (8)

When the distance in the Y direction between a center C of the structure 60 closest to the first point P1 among the plurality of structures 60 and the inner wall 10b is defined as L_{c1h}, the following Expression (9) is preferably satisfied.

0<L_{c1h}≤Lₕ/(2N) (9)

Further, when the distance in the X direction between the center C of the structure 60 closest to the second point P2 among the plurality of structures 60 and the inner wall 10b is defined as L_{c1w}, the following Expression (10) is preferably satisfied.

0<L_{c1w}≤L_{w}/(2N) (10)

When the distance in the Y direction between the centers C of two adjacent structures 60 is defined as L_{c2h}, the following Expression (11) is preferably satisfied.

L_{c2h}≤(Lₕ-D/2-L_{c1h})/(N−1) (11)

Further, when the distance in the X direction between the centers C of two adjacent structures 60 is defined as L_{c2w}, the following Expression (12) is preferably satisfied.

L_{c2w}≤(L_{w}-D/2-L_{c1w})/(N−1) (12)

Here, two adjacent structures 60 refer to a combination of one structure 60 and another structure 60 having a center C closest to the center C of the one structure 60.

### 3.2 Operation

Operation of the gas laser device 2 according to the present embodiment is similar to that of the comparative example except that the effect caused by provision of the vortex dividing member 40 in the container 10a is different.

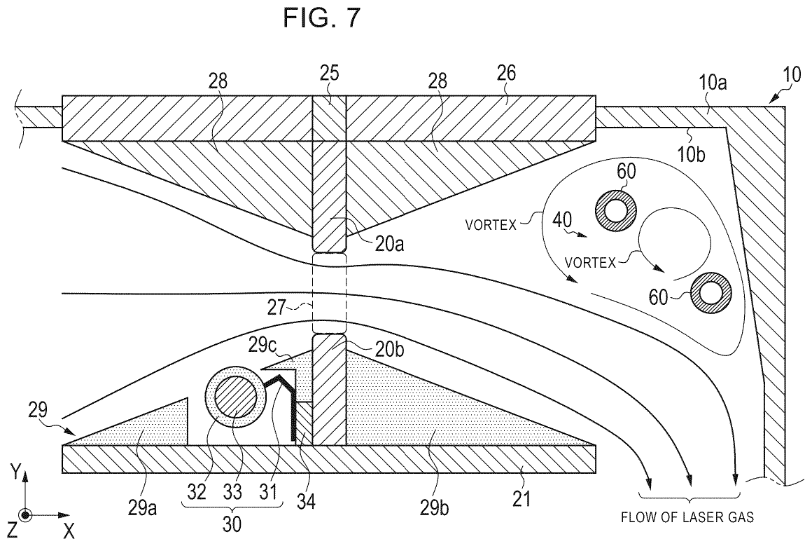

FIG. 7 shows an example of the flow of the laser gas in the second embodiment. As shown in FIG. 7, in the present embodiment, similarly to the first embodiment, the vortex is divided into a plurality of small vortices by the vortex dividing member 40.

### 3.3 Effect

In the present embodiment, similarly to the first embodiment, the vortex is divided into a plurality of small vortices by the vortex dividing member 40, so that the energy stability of the pulse laser light PL is improved. Further, by performing a simulation, in the present embodiment, it was confirmed that the flow rate was improved by 1% as compared with the comparative example.

Further, in the present embodiment as well, the vortex dividing member 40 is configured by the plurality of structures 60 arranged discretely along the flow of the laser gas, and since the area thereof for reflecting acoustic waves is small, it is possible to suppress acoustic waves from being reflected by the vortex dividing member 40 and returning to the discharge space 27. Further, in the present embodiment, since the structure 60 has a circular outer shape in a cross section, acoustic waves can be further suppressed from returning to the discharge space 27. By suppressing acoustic waves from returning to the discharge space 27 as described above, the energy stability of the pulse laser light PL is further improved.

### 4. Third Embodiment

### 4.1 Configuration

The gas laser device 2 according to a third embodiment of the present disclosure has a configuration similar to that of the gas laser device 2 according to the first embodiment except that the configuration of the laser chamber 10 is different.

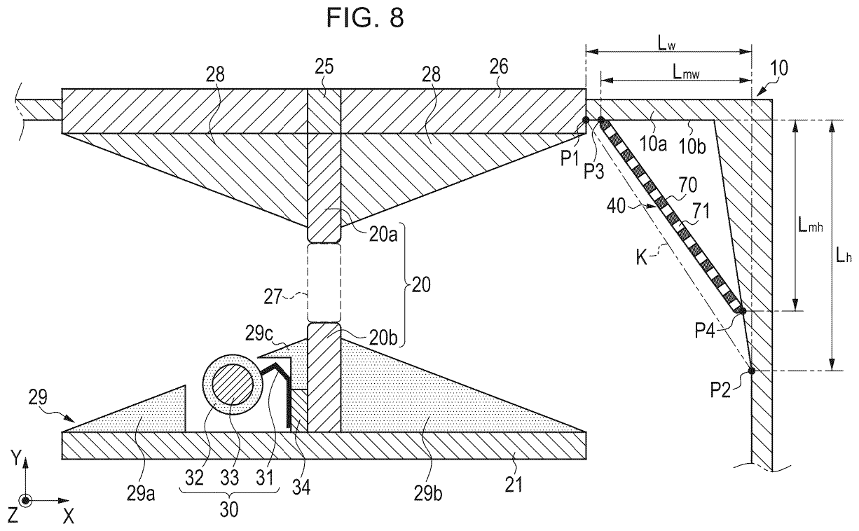

FIG. 8 shows in detail the configuration of the vicinity of the main electrode 20 of the laser chamber 10 according to the third embodiment. In the present embodiment, similarly to the first embodiment, the vortex dividing member 40 for dividing the vortex described above is provided in the container 10a. In the present embodiment, the vortex dividing member 40 is a mesh plate 70 arranged along the flow of the laser gas on the downstream side with respect to the insulating guide 28 arranged on the downstream side of the cathode electrode 20a.

The mesh plate 70 extends in the Z direction while maintaining the same cross-sectional shape, and both end portions in the Z direction are fixed to the inner wall 10b of the container 10a. Further, both ends of the mesh plate 70 in the XY plane are in contact with the inner wall 10b. In addition to having the both end portions thereof fixed to the inner wall 10b, the mesh plate 70 may be supported by a support column (not shown) connected to the inner wall 10b.

The mesh plate 70 is a mesh-like member and has a plurality of openings 71 arranged two-dimensionally. That is, the mesh plate 70 is configured by a plurality of structures discretely arranged along the flow of the laser gas.

The mesh plate 70 is preferably formed of, for example, aluminum on which nickel electroless plating is performed, alumina ceramic, nickel, or the like.

The mesh plate 70 is preferably arranged such that the following conditions are satisfied in order to divide the vortex and suppress acoustic waves from returning to the discharge space 27. Here, definitions of the first point P1, the second point P2, the first distance Lₕ, and the second distance L_{w} are similar to those in the first embodiment.

Of the two points at which the mesh plate 70 and the inner wall 10b are in contact with each other in the XY plane, a point closer to the first point P1 is referred to as a third point P3, and a point closer to the second point P2 is referred to as a fourth point P4. When the distance between the third point P3 and the fourth point P4 in the Y direction is defined as Lₘₕ, the following Expression (13) is preferably satisfied.

0.25Lₕ≤Lₘₕ≤Lₕ (13)

Further, when the distance between the third point P3 and the fourth point P4 in the X direction is defined as L_{mw}, the following Expression (14) is preferably satisfied.

0.25L_{w}≤L_{mw}≤L_{w} (14)

As described above, the mesh plate 70 is preferably arranged in a space defined by the inner wall 10b and a straight line K connecting the first point P1 and the second point P2.

In the present embodiment, the mesh plate 70 is arranged on a straight line connecting the third point P3 and the fourth point P4 in the XY plane, but may be arranged on a curved line connecting the third point P3 and the fourth point P4.

In order to suppress acoustic waves from returning to the discharge space 27, the mesh plate 70 preferably has, for example, two or more openings 71 per square inch. Further, the mesh plate 70 preferably has an aperture ratio of 50% or more and 80% or less.

### 4.2 Operation

Operation of the gas laser device 2 according to the present embodiment is similar to that of the comparative example except that the effect caused by provision of the vortex dividing member 40 in the container 10a is different.

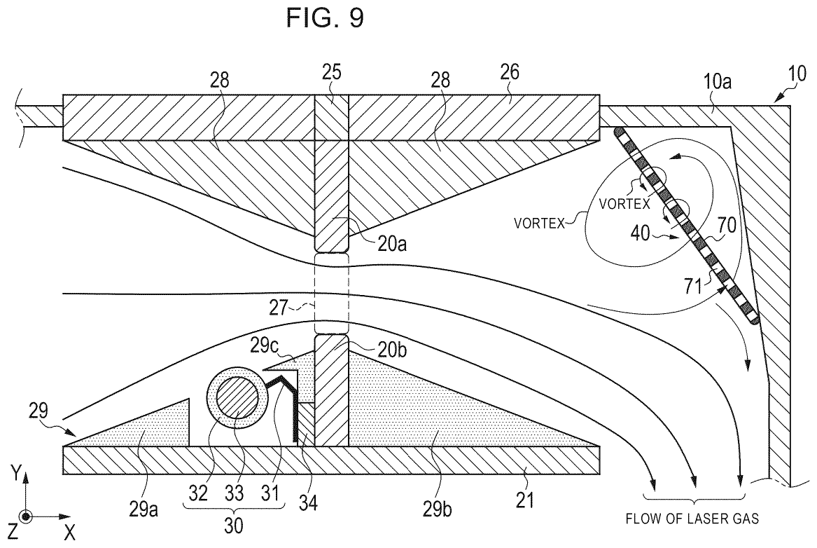

FIG. 9 shows an example of the flow of the laser gas in the third embodiment. As shown in FIG. 9, in the present embodiment, similarly to the first embodiment, the vortex is divided into a plurality of small vortices by the vortex dividing member 40.

### 4.3 Effect

In the present embodiment, similarly to the first embodiment, the vortex is divided into a plurality of small vortices by the vortex dividing member 40, so that the energy stability of the pulse laser light PL is improved. Further, by performing a simulation, in the present embodiment, it was confirmed that the flow rate was improved by 1% as compared with the comparative example.

Further, in the present embodiment, the vortex dividing member 40 is the mesh plate 70 configured by a plurality of structures arranged discretely along the flow of the laser gas, and since the area thereof for reflecting acoustic waves is small, it is possible to suppress acoustic waves from being reflected by the vortex dividing member 40 and returning to the discharge space 27. By suppressing acoustic waves from returning to the discharge space 27 as described above, the energy stability of the pulse laser light PL is further improved.

### 5. Fourth Embodiment

### 5.1 Configuration

The gas laser device 2 according to a fourth embodiment of the present disclosure has a configuration similar to that of the gas laser device 2 according to the first embodiment except that the configuration of the laser chamber 10 is different.

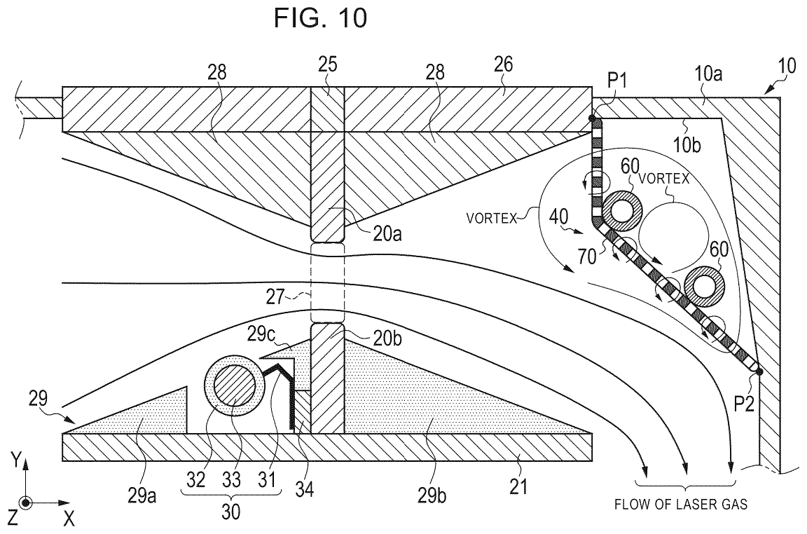

FIG. 10 shows in detail the configuration of the vicinity of the main electrode 20 of the laser chamber 10 according to the fourth embodiment. In the present embodiment, similarly to the first embodiment, the vortex dividing member 40 for dividing the vortex described above is provided in the container 10a. In the present embodiment, the vortex dividing member 40 is configured by combining the plurality of structures 60 and the mesh plate 70.

The structure 60 has the same configuration as the structure 60 described in the second embodiment. The mesh plate 70 has the same configuration as the mesh plate 70 described in the third embodiment. The size and arrangement of the plurality of structures 60 may be the same as those in the second embodiment. The arrangement and aperture ratio of the mesh plate 70 may be the same as those in the second embodiment.

The mesh plate 70 is arranged on a curved line so as to avoid the plurality of structures 60. In the present embodiment, the plurality of structures 60 are arranged in a space surrounded by the mesh plate 70 and the inner wall 10b, and the plurality of structures 60 are in contact with the mesh plate 70.

### 5.2 Operation

Operation of the gas laser device 2 according to the present embodiment is similar to that of the comparative example except that the effect caused by provision of the vortex dividing member 40 in the container 10a is different.

FIG. 10 shows an example of the flow of the laser gas in the fourth embodiment. As shown in FIG. 10, in the present embodiment, the vortex may be divided into a plurality of smaller vortices by the vortex dividing member 40 than in the second embodiment or the third embodiment.

### 5.3 Effect

According to the present embodiment, since the vortex can be divided into a plurality of smaller vortices than in the second embodiment or the third embodiment, the flow path resistance can be further reduced, and the flow rate of the laser gas flowing through the discharge space 27 can be further improved. As a result, the energy stability of the pulse laser light PL can be further improved.

Here, the vortex dividing member 40 may be configured by combining the plurality of structures 50 and the mesh plate 70. The structure 50 has the same configuration as the structure 50 described in the first embodiment.

### 6. Electronic Device Manufacturing Method

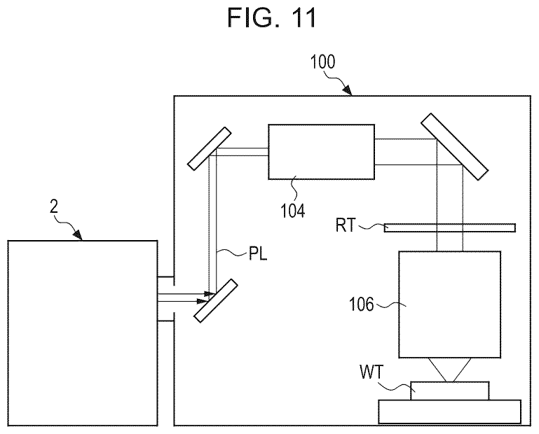

FIG. 11 schematically shows a configuration example of the exposure apparatus 100. The exposure apparatus 100 includes an illumination optical system 104 and a projection optical system 106. For example, the illumination optical system 104 illuminates a reticle pattern of a reticle (not shown) arranged on a reticle stage RT with the pulse laser light PL incident from the gas laser device 2. The projection optical system 106 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 100 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

Here, not limited to the manufacturing of an electronic device, the gas laser device 2 may be used for laser processing such as drilling.

The description above is intended to be illustrative and the present disclosure is not limited thereto. Therefore, it would be obvious to those skilled in the art that various modifications to the embodiments of the present disclosure would be possible without departing from the spirit and the scope of the appended claims.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A laser chamber of a gas laser device configured to output laser light, the laser chamber comprising:
a container filled with a laser gas;
a first electrode extending in a first direction and arranged in the container;
a second electrode arranged at a position closer to an inner wall of the container than the first electrode while extending in the first direction and facing the first electrode in a second direction orthogonal to the first direction;
a fan configured to cause the laser gas to flow through a discharge space between the first electrode and the second electrode;
an insulating guide arranged on a downstream side of the second electrode; and
a vortex dividing member including a plurality of structures extending in the first direction and arranged discretely along a direction in which the laser gas flows on a downstream side of the insulating guide, and configured to divide a vortex generated by a part of a flow of the laser gas.

2. The laser chamber according to claim 1,
wherein each of the structures is a bracket including two straight portions whose cross sections in a plane perpendicular to the first direction are perpendicular to each other.

3. The laser chamber according to claim 2,
wherein S≤Lₕ/(2N) and S≤L_{w}/(2N) are satisfied,
where, in the plane perpendicular to the first direction, a point at which the inner wall is in contact with the insulating guide on the downstream side of the second electrode is defined as a first point, a point at which an inclined surface of the inner wall becomes parallel to the second direction is defined as a second point, a direction orthogonal to the first direction and the second direction is defined as a third direction, a distance in the second direction between the first point and the second point is defined as Lₕ, a distance in the third direction between the first point and the second point is defined as L_{w}, a number of the structures configuring the vortex dividing member is defined as N, and a length of each of the two straight portions is defined as S.

4. The laser chamber according to claim 3,
wherein 0<Lₐ₁ₕ≤Lₕ/(2N) is satisfied, where a distance in the second direction between an apex of the structure closest to the first point among the plurality of structures and the inner wall is defined as Lₐ₁ₕ.

5. The laser chamber according to claim 4,
wherein 0<L_{a1w}L_{w}/(2N) is satisfied, where a distance in the third direction between an apex of the structure closest to the second point among the plurality of structures and the inner wall is defined as L_{a1w}.

6. The laser chamber according to claim 5,
wherein Lₐ₂ₕ≤(Lₕ-S/2-Lₐ₁ₕ)/(N−1) is satisfied, where a distance in the second direction between apexes of two of the structures adjacent to each other is defined as Lₐ₂ₕ.

7. The laser chamber according to claim 6,
wherein L_{a2w}≤(L_{w}-S/2-L_{a1w})/(N−1) is satisfied, where a distance in the third direction between the apexes of two of the structures adjacent to each other is defined as L_{a2w}.

8. The laser chamber according to claim 1,
wherein each of the structures is a cylinder having a circular outer shape in a cross section in a plane perpendicular to the first direction.

9. The laser chamber according to claim 8,
wherein D≤Lₕ/(2N) and D≤L_{w}/(2N) are satisfied,
where, in the plane perpendicular to the first direction, a point at which the inner wall is in contact with the insulating guide on the downstream side of the second electrode is defined as a first point, a point at which an inclined surface of the inner wall becomes parallel to the second direction is defined as a second point, a direction orthogonal to the first direction and the second direction is defined as a third direction, a distance in the second direction between the first point and the second point is defined as Lₕ, a distance in the third direction between the first point and the second point is defined as L_{w}, a number of the structures configuring the vortex dividing member is defined as N, and an outer diameter of each of the structures is defined as D.

10. The laser chamber according to claim 9,
wherein 0<L_{c1h}<Lₕ/(2N) is satisfied, where a distance in the second direction between a center of the structure closest to the first point among the plurality of structures and the inner wall is defined as L_{c1h}.

11. The laser chamber according to claim 10,
wherein 0<L_{c1w}≤L_{w}/(2N) is satisfied, where a distance in the third direction between a center of the structure closest to the first point among the plurality of structures and the inner wall is defined as L_{c1w}.

12. The laser chamber according to claim 11,
wherein L_{c2h}≤(Lₕ-S/2-L_{c1h})/(N−1) is satisfied, where a distance in the second direction between centers of two of the structures adjacent to each other is defined as L_{c2h}.

13. The laser chamber according to claim 12,
wherein L_{c2w}≤(L_{w}-S/2-L_{c1w})/(N−1) is satisfied, where a distance in the third direction between the centers of two of the structures adjacent to each other is defined as L_{c2w}.

14. The laser chamber according to claim 8,
wherein each of the structures is a hollow cylinder having a hollow portion.

15. The laser chamber according to claim 1,
wherein the vortex dividing member is a mesh plate.

16. The laser chamber according to claim 15,
wherein the vortex dividing member is arranged in a space defined by the inner wall and a straight line connecting a first point and a second point,
where, in a plane perpendicular to the first direction, a point at which the inner wall is in contact with the insulating guide on the downstream side of the second electrode is defined as the first point, and a point at which an inclined surface of the inner wall becomes parallel to the second direction is defined as the second point.

17. The laser chamber according to claim 1,
wherein the vortex dividing member includes a combination of a mesh plate and a plurality of cylinders each having a circular outer shape in a cross section in a plane perpendicular to the first direction.

18. The laser chamber according to claim 1,
wherein the vortex dividing member includes a combination of a mesh plate and a plurality of brackets each including two straight portions whose cross sections in a plane perpendicular to the first direction are perpendicular to each other.

19. A gas laser device configured to output laser light and including an optical resonator and a laser chamber arranged to cause an optical path of the optical resonator to pass therethrough,
the laser chamber including:
a container filled with a laser gas;
a first electrode extending in a first direction and arranged in the container;
a second electrode arranged at a position closer to an inner wall of the container than the first electrode while extending in the first direction and facing the first electrode in a second direction orthogonal to the first direction;
a fan configured to cause the laser gas to flow through a discharge space between the first electrode and the second electrode;
an insulating guide arranged on a downstream side of the second electrode; and
a vortex dividing member including a plurality of structures extending in the first direction and arranged discretely along a direction in which the laser gas flows on a downstream side of the insulating guide, and configured to divide a vortex generated by a part of a flow of the laser gas.

20. An electronic device manufacturing method, comprising:
generating laser light using a gas laser device;
outputting the laser light to an exposure apparatus; and
exposing a photosensitive substrate to the laser light in the exposure apparatus to manufacture an electronic device,
the gas laser device being configured to output the laser light and including an optical resonator and a laser chamber arranged to cause an optical path of the optical resonator to pass therethrough, and
the laser chamber including:
a container filled with a laser gas;
a first electrode extending in a first direction and arranged in the container;
a second electrode arranged at a position closer to an inner wall of the container than the first electrode while extending in the first direction and facing the first electrode in a second direction orthogonal to the first direction;
a fan configured to cause the laser gas to flow through a discharge space between the first electrode and the second electrode;
an insulating guide arranged on a downstream side of the second electrode; and
a vortex dividing member including a plurality of structures extending in the first direction and arranged discretely along a direction in which the laser gas flows on a downstream side of the insulating guide, and configured to divide a vortex generated by a part of a flow of the laser gas.
